(19) United States
(12) Patent Application Publication
(10) Pub. No.: US 2021/0287925 A1
(43) Pub. Date: Sep. 16, 2021

(54) SUBSTRATE SUPPORT PLATE AND SEMICONDUCTOR MANUFACTURING APPARATUS

(71) Applicant: Kioxia Corporation, Tokyo (JP)

(72) Inventor: Masashi SHIMOMURA, Yokkaichi (JP)

(73) Assignee: Kioxia Corporation, Tokyo (JP)

(21) Appl. No.: 17/016,622

(22) Filed: Sep. 10, 2020

(30) Foreign Application Priority Data
Mar. 16, 2020 (JP) 2020-045535

(51) Int. Cl. H01L 21/683; H01J 37/32; C23C 16/458; C23C 14/50

(52) U.S. Cl. CPC H01L 21/6833; H01J 37/32715; H01J 2237/2007; C23C 14/50; C23C 16/4583

(57) ABSTRACT

A substrate support plate includes a base plate; at least one spacer arranged on the base plate such that the at least one spacer is restrained from moving relative to the base plate without resort to an adhesive; and a top plate having an upper surface capable of holding a substrate thereon, the top plate being fixed to the base plate with the at least one spacer therebetween.

### CROSS-REFERENCE TO RELATED APPLICATIONS

This application is based upon and claims the benefit of priority from Japanese Patent Application No. 2020-045535, filed on Mar. 16, 2020; the entire contents of which are incorporated herein by reference.

### FIELD

Embodiments of the present disclosure relate to a substrate support plate and a semiconductor manufacturing apparatus.

### BACKGROUND

A support plate for supporting a semiconductor substrate is provided in a semiconductor manufacturing apparatuses such as an etch apparatus, a film deposition apparatus, or the like.

### BRIEF DESCRIPTION OF DRAWINGS

FIG. 1 is a cross-sectional view illustrating a construction of a plasma processing apparatus as an example of a semiconductor manufacturing apparatus according to one embodiment;

FIG. 2 is a plan view illustrating a support plate;

FIG. 3 is a cross-sectional view taken along a I-I line of the support plate illustrated in FIG. 2;

FIGS. 4A and 4B are plan views illustrating examples of arrangement patterns of the spacers;

FIG. 5 is an enlarged view illustrating a part of the cross-sectional view of FIG. 3;

FIGS. 6A through 6C are enlarged views illustrating parts of a cross section of a support plate according to a comparative example; and

FIG. 7 is an enlarged view illustrating a part of a cross section of the support plate according to a modification of the embodiment.

### DETAILED DESCRIPTION

A temperature of the support plate provided in a semiconductor manufacturing apparatuses such as an etch apparatus, a film deposition apparatus, or the like is adjusted ranging from low temperatures to high temperatures so that the semiconductor substrate thereon is set to be a predetermined temperature depending on processes such as etching, the film deposition, or the like. Additionally, the support plate is cooled through heat radiation when there is no in-coming heat from plasma, or cooling by the refrigerant, at the time of transferring the semiconductor substrate in or out. When the support plate is heated and cooled repeatedly in such a manner, a life of the support plate may shorten or a trouble may occur, which results in frequent replacement of the support plate.

One embodiment of the present disclosure provides a substrate support plate which can reduce replacement frequency and a semiconductor manufacturing apparatus including such a substrate support plate.

According to one embodiment of the present disclosure, a substrate support plate is provided which includes a base plate; at least one spacer arranged on the base plate such that the at least one spacer is restrained from moving relative to the base plate without resort to an adhesive; and a top plate having an upper surface capable of holding a substrate thereon, the top plate being fixed to the base plate with the at least one spacer therebetween.

Non-limiting, exemplary embodiments of the present disclosure will now be described with reference to the accompanying drawings. In the drawings, the same or corresponding reference marks are given to the same or corresponding members or components, and redundant explanations will be omitted. It is to be noted that the drawings are illustrative of the disclosure, and there is no intention to indicate scale or relative proportions among the members or components. Therefore, the specific size should be determined by a person having ordinary skill in the art in view of the following non-limiting embodiments.

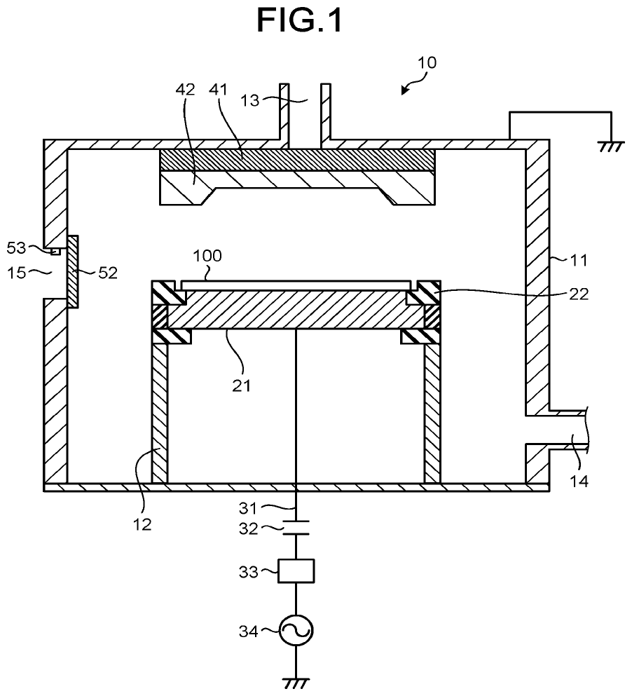

FIG. 1 is a cross-sectional view schematically illustrating a construction of a plasma processing apparatus as an example of a semiconductor manufacturing apparatus according to one embodiment. As illustrated, a plasma processing apparatus 10 has a chamber 11 that is provided with a gas inlet 13 through which a process gas to be used for plasma processing is supplied, a gas outlet 14 through which the process gas is exhausted. The gas inlet 13 is connected to a process gas source (not illustrated) by a predetermined pipe and the like, and an exhausting apparatus such as a vacuum pump (not illustrated) is connected to the gas outlet 14. Additionally, the chamber 11 is formed of metal such as aluminum or the like, or alloys such as stainless steel or the like. The chamber 11 is grounded.

A support plate 21 is provided inside the chamber 11. The support plate 21 has an electrostatic chuck, with which a substrate 100 subject to plasma processing is held on an upper surface of the support plate 21.

The support plate 21 is fixed by support members 12 so as to be located in substantially a center in the chamber 11. Additionally, a dummy ring 22 is provided along a circumferential surface of the support plate 21. The dummy ring 22 is provided to adjust an electric field so that an electric field is not deflected around a circumferential edge portion of the substrate 100 with respect to a vertical direction (a direction that is perpendicular to the upper surface of the substrate 100 on the support plate 21) when the substrate 100 is processed.

Additionally, a power supplying line 31 for supplying a high frequency power is connected to the support plate 21, and a blocking capacitor 32, a matching box 33, and a high frequency power source 34 are connected to the power supplying line 31. A high frequency power of a predetermined frequency is supplied to the support plate 21 from the high frequency power source 34. Namely, the support plate 21 also functions as a bottom electrode.

An upper electrode 42 is provided above the support plate 21 so as to face the support plate 21. The upper electrode 42 is fixed to a member 41 provided on a top plate in the chamber 11 so that the upper electrode 42 faces in parallel with the support plate 21 with a predetermined distance away from the support plate 21. With such a structure, a pair of parallel plate electrodes is constructed with the upper electrode 42 and the support plate 21. The upper electrode 42 has a shape of, for example, disk. The upper electrode 42 may be made of, for example, silicon. Note that, the upper electrode 42 and the member 41 are provided with a plurality of gas feed paths (not illustrated) to penetrate therethrough in a thickness direction. With this, a process gas is introduced into the chamber 11 from the gas inlet 13 through the gas feed paths.

An opening 15, through which the substrate 100 is transferred in and out, is provided on a sidewall of the chamber 11. A shutter 52 is provided in the opening 15. The shutter 52 has a function to separate the inside and the outside of the chamber 11, and may be open to allow the inside and the outside of the chamber 11 to be in communication with each other when the substrate is transferred in and out from the chamber 11. The opening 15 is provided with a sensor 53 that detects a position of the substrate 100 with respect to a transfer arm (not illustrated) that transfers the substrate 100 into the chamber 11. For example, the sensor 53 may be a distance sensor.

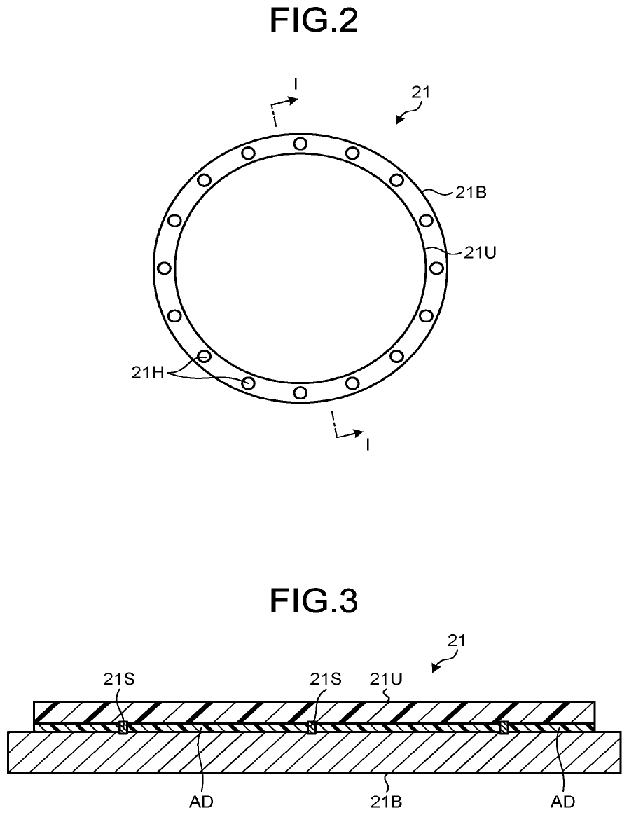

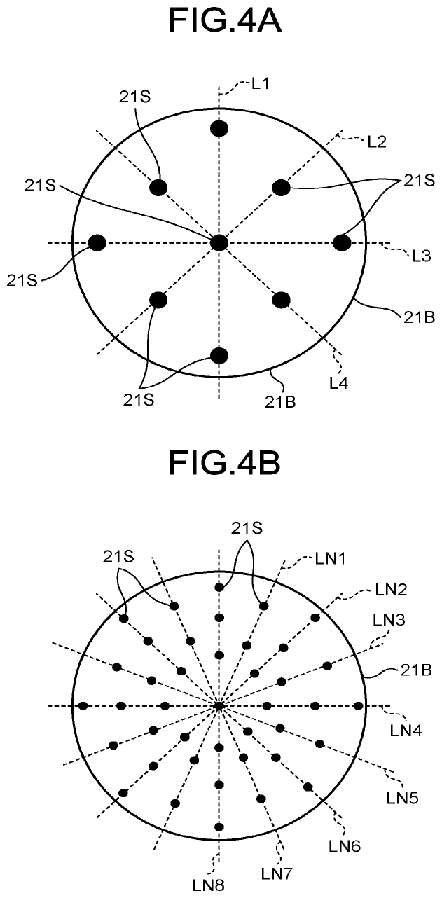

FIG. 2 is a plan view schematically illustrating a support plate 21. FIG. 3 is a cross-sectional view taken along a I-I line of the support plate 21 illustrated in FIG. 2. FIGS. 4A and 4B are plan views illustrating examples of arrangement patterns of the spacers (a view illustrating a top surface of a base plate 21B before a top plate 21U is adhered to the base plate 21B). Note that, in FIG. 3, electrodes for the electrostatic chuck provided in the support plate 21 is omitted.

As illustrated in FIG. 2, the support plate 21 has a base plate 21B and a top plate 21U. The base plate 21B has a shape of disk, and may be formed of, for example, metal such as aluminum (Al). Additionally, an unillustrated conduit is formed inside the base plate 21B. A fluid, which may be temperature-regulated by an outside temperature regulator (not illustrated), is supplied to the conduit, and thus a temperature of the base plate 21B is adjusted.

The top plate 21U Additionally has a shape of disk. The top plate 21U has an outer diameter smaller than an outer diameter of the base plate 21B, and arranged on the base plate 21B concentrically to the base plate 21B. On an upper surface of the top plate 21U, a plurality of protrusions (not illustrated) to support the substrate 100 are formed approximately at equal intervals for uniform temperature distribution within the substrate 100. For example, an inert gas (e.g., a helium gas) is supplied to a space between the top plate 21U and a backside of the substrate 100, the space being formed by those protrusions. Additionally, the top plate 21U may be formed of, for example, ceramic materials such as Al₂O₃ and AlN.

Note that holes 21H provided along an outer circumference of the base plate 21B illustrated in FIG. 2 are used when attaching the support plate 21 to the support members 12 with screws and the like.

Referring to FIG. 3, the top plate 21U and the base plate 21B are attached to each other by an adhesive AD. Additionally, a plurality of spacers 21S are provided between the top plate 21U and the base plate 21B. The spacers 21S are provided to maintain constant a distance between the top plate 21U and the base plate 21B. Heat of the temperature-regulated base plate 21B can be transmitted to the top plate 21U uniformly by maintaining the distance between the top plate 21U and the base plate 21B, and thus the top plate 21U and the substrate 100 placed thereon can be made uniform in temperature.

Each of the spacers 21S can have a shape of, for example, column. In this case, a diameter of the column may be, for example, from 1 mm about several mm, and, a height of the column may be, for example, from 1 mm to about 2 mm. Additionally, the spacers 21S are formed of metal in this embodiment. Specifically, the spacers 21S can be formed of metal that is the same as the metal constructing the base plate 21B. However, the spacers 21S may be formed of a ceramic material. Moreover, the spacers 21S may be formed of a ceramic material that is the same as the ceramic material constructing the top plate 21U.

Explanation is now made on a arrangement example of the spacers 21S. FIGS. 4A and 4B are plan views illustrating examples of arrangement patterns of the spacers 21S on the base plate 21B. As illustrated, the spacers 21S may be placed radially or along concentric circles. For example, in FIG. 4A, nine spacers 21S are placed radially on the base plate 21B. Specifically, one of the spacers 21S is placed in a center of the base plate 21B, and two spacers 21S are placed along each of four virtual straight lines L1, L2, L3 that extend passing through the center at angular intervals of 45° with each other, so as to be centrally symmetric to the center of the base plate 21B.

Incidentally, the arrangement of the spacers 21S illustrated in FIG. 4A can also be expressed as follows. Three spacers 21S are equally placed at a first interval along the virtual straight line L1; and another three spacers 21S are equally placed at the first interval along the virtual straight line L3 that intersects at the right angle with the virtual straight line L1. On the other hand, three spacers 21S are equally placed at a second interval narrower than the first interval along the virtual straight line L2 that intersects at 45° with the virtual straight line L1; and another three spacers 21S are equally placed at the second interval along the virtual straight line L4 that intersects at the right angle with the virtual straight line L2. As a result, in this example of FIG. 4A, it can be said that the spacers 21S are arranged in a 3×3 matrix on the base plate 21B. Namely, the nine spacers 21S are arranged radially and in a matrix on the base plate 21B.

With such an arrangement of the spacers 21S as FIG. 4A, the top plate 21U is supported without being deflected, and load to be applied onto the spacers 21S from the top plate 21U can be deconcentrated uniformly. Namely, in order to disperse the load and not to deflect the top plate 21U, without limiting to but, at least nine spacers 21S may be used.

Additionally, in FIG. 4B, forty-one spacers 21S are arranged radially on the base plate 21B. Specifically, one spacer 21S is arranged in the center of the base plate 21B. Additionally, along eight virtual straight lines LN1, LN2, LN3, LN4, LN5, LN6, LN7, and LN8 that extend through the center of the base plate 21B at angular intervals of 22.5°, plural spacers 21S are arranged. More specifically, along the virtual straight lines LN1, LN3, LN5, LN7, two spacers 21S are arranged centrally symmetric to the center of the base plate 21B; and along virtual straight line LN2, LN4, LN6, LN8, three spacers 21S are arranged centrally symmetric to the center of the base plate 21B.

When the spacers 21S are arranged as illustrated in FIG. 4B, a diameter of the spacers 21S can be reduced in comparison with a case where the spacers 21S are arranged as illustrated in FIG. 4A. Therefore, an area where one spacer 21S contacts the base plate 21B and the top plate 21U becomes small, and thus the base plate 21B and the top plate 21U contact each other by way of an adhesive at a larger area around each spacer 21S. With this, a difference in thermal conduction between the base plate 21B and the top plate 21U is not apt to occur, which may improve a temperature uniformity of the top plate 21U.

Therefore, the number of spacers 21S may be determined so that the top plate 21U is not deflected and thermal conduction becomes uniform while maintaining a distance between the top plate 21U and the base plate 21B uniform.

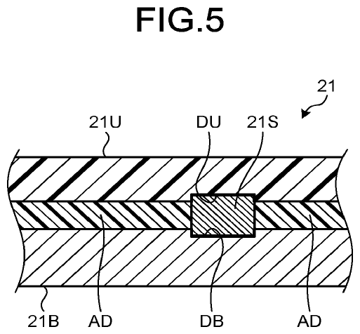

Next, explanation is made on a relationship of the base plate 21B, the spacers 21S and the top plate 21U. FIG. 5 is an enlarged view of FIG. 3. As illustrated, a depressed portion DB is formed to correspond to the spacer 21S in the base plate 21B. The depressed portion DB has a shape of hollow bottomed cylinder. As illustrated, a lower end of the spacer 21S is fitted into the depressed portion DB without intervention of an adhesive. The depressed portion DB has an inner diameter so that the spacer 21S may be fitted tightly thereinto as far as the spacer 21S is removable. Additionally, a depth of the depressed portion DB may be determined taking a height of the spacer 21S into consideration. For example, a depth of the depressed portion DB is smaller than a half of a height of the spacer 21S, and may be determined so that the spacer 21S is not easily removed from the depressed portion DB.

Additionally, the depressed portion DU is formed at a position in the top plate 21U, the position facing the depressed portion DB of the base plate 21B. As illustrated, an upper end of the spacer 21S is fitted into the depressed portion DU. The depressed portion DU also has a shape of hollow bottomed cylinder. An inner diameter of the depressed portion DU may be set so that the spacer 21S is fitted tightly thereinto as far as the spacer 21S is removable. Additionally, a depth of the depressed portion DU may be determined taking a height of the spacer 21S into consideration. For example, a depth of the depressed portion DU is smaller than a half of a height of the spacer 21S, and may be determined so that the spacer 21S is not easily removed from the depressed portion DU.

As described above, the top plate 21U is held by the base plate 21B with a distance therebetween being maintained at a predetermined constant distance by the multiple spacers 21S. Adhesive AD is filled in a space between the top plate 21U and the base plate 21B, and thus the top plate 21U and base plate 21B are adhered with each other.

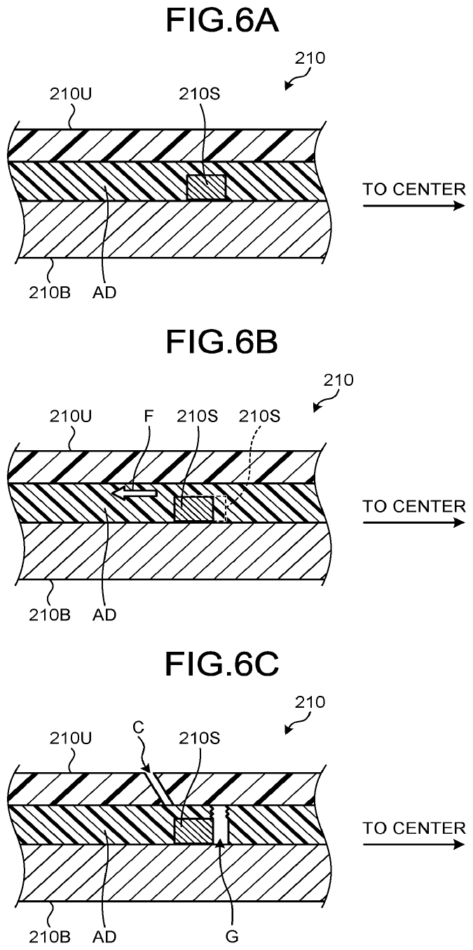

Next, explanation is made on effects exerted by the support plate 21 constructed as above by comparing a comparative example. FIGS. 6A to 6C are partially enlarged cross-sectional views schematically illustrating a section of a support plate 210 according to the comparative example. Referring to FIG. 6A, the support plate 210 has a base plate 210B, a top plate 210U, and a spacer 210S placed on the base plate 210B. A space defined by the base plate 210B, the top plate 210U, and the spacer 210S is filled with an adhesive AD. With this, the base plate 210B and the top plate 210U are adhered, and the spacer 210S is also fixed with respect to the base plate 210B and the top plate 210U. However, the adhesive AD is not applied between the spacer 210S and the base plate 210B. Namely, the spacer 210S is surrounded by the adhesive AD and thus fixed to the base plate 210B.

When the support plate 210 having such a construction is used in a chamber of a plasma processing apparatus, the support plate 210 is heated and then cooled every time the substrate 100 is processed. Because the adhesive AD is also heated and then cooled, the adhesive AD is repeatedly expanded and shrunk. With such expansion and shrinkage of the adhesive AD, the spacer 21S is subjected to force that may cause reciprocating movement of the spacer 21S on the base plate 21B. Namely, the adhesive AD is applied around the spacer 21S, and may move the spacer 21S by the expansion and shrinkage thereof, while the adhesive AD inherently fixes the spacer 21S.

When such force acts on the spacer 210S repeatedly, a gap is generated between the adhesive AD and the spacer 210S, and the spacer 210S may move, as illustrated in FIG. 6B. In FIG. 6B, an original position of the spacer 210S is represented by a dotted line, and a position of the spacer 210S that has moved is represented by a solid line. Such a movement may be caused in a direction away from a center of the support plate 210. This is because the adhesive AD is expanded to greater extent toward an outer circumference of the support plate 210 rather than toward the center of the support plate 210. When the spacer 210S moves, a shear stress is applied to the top plate 210U, as illustrated by an arrow F in FIG. 6C. As a result, as illustrated in FIG. 6C, a crack C may occur to the top plate 210U. Additionally, by such a movement of the spacer 210S, the adhesive AD may be cleaved and thus a gap G may be generated at a rear end side thereof in a direction along which the spacer 210S moves.

When the crack C is generated, because a contact state is changed between the top plate 210U and the substrate 100 placed thereon, a temperature uniformity of the substrate 100 may be degraded. Additionally, when the support plate 210 is used in a chamber of a plasma processing apparatus, anomalous discharge may occur between the support plate 210 and an upper electrode due to the crack C. Therefore, a visual check, for example, is performed to check whether the crack C occurs. Then, when the crack C is confirmed to occur, the support plate 210 is replaced. Alternatively, the support plate 210 needs to be replaced at relatively short intervals to prevent occurrence of the crack C.

On the other hand, according to the support plate 21 of this embodiment, the spacer 21S is fitted at the bottom end thereof into the depressed portion DB of the base plate 21B and at the upper end thereof into the depressed portion DU of the top plate 21U. Namely, the spacer 21S is restrained from moving by the depressed portion DB rather than by the adhesive AD therearound. Therefore, the spacer 21S is restrained from moving with respect to the base plate 21B even when the adhesive AD expands and shrinks. Accordingly, the top plate 21U is less subjected to shear stress, and thus the occurrence of a crack can be reduced in the top plate 21U. Therefore, a usable period of the support plate 21 may be increased; and replacement frequency may be reduced; and thus a running cost of a semiconductor manufacturing apparatus can be reduced.

### Modification

Explanation is now made on a support plate according to modification of the embodiment. The support plate according to the modification differs in a cross-sectional structure from the support plate 21 according to the above embodiment, and is the same in other construction. In the following, the support plate according to the modification is explained, focusing on the difference.

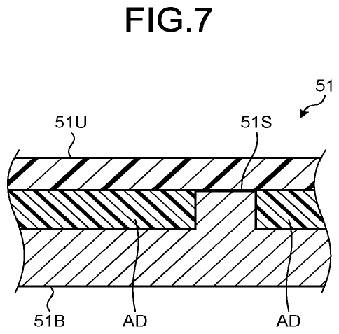

FIG. 7 is a view illustrating a cross section of the support plate. FIG. 7, which corresponds to FIG. 5, illustrates a part of the cross section of the support plate according to the modification in an enlarged manner. As illustrated, a support plate 51 according to the modification has a base plate 51B, a spacer(s) 51S and a top plate 51U. An adhesive AD is filled in a space defined by the base plate 51B, the spacer 51S, and the top plate 51U, and thus, the base plate 51B and the top plate 51U are adhered with each other. Here, the spacer 51S is formed as a protrusion portion protruding from the base plate 51B. Such a spacer 51S may be formed by grinding the base plate 51B from the surface thereof so that the spacer 51S remains thereon.

Because such a spacer 51S is formed as a single body with the base plate 51B, movement of the spacer 51S by thermal expansion of the adhesive AD is restrained, and thus shear stress is less applied to the top plate 51U from the adhesive AD. Therefore, even in the support plate 51 according to the modification, occurrence of the crack of the top plate 51U can also be reduced.

On the other hand, a depressed portion DU may be formed in the top plate 51U, corresponding to a position where the spacer 51S is arranged, and an upper end of the spacer 21S may be fitted into this depressed portion DU.

Incidentally, in the above embodiment, the top plate 21U is provided with the depressed portion DU, and the upper end of the spacer 21S is fitted into the depressed portion DU. With this, installation of the top plate 21U to the base plate 21B can be reinforced. However, the depressed portion DU is not necessarily provided to the top plate 21U. This is because the spacer 21S is restrained from moving when the depressed portion DB is provided in the base plate 21B, and because the top plate 21U and the base plate 21B can be tightly adhered. Similarly, the depressed portion DU is not necessarily provided to the top plate 51U in the modification (FIG. 7).

Additionally, although the plasma processing apparatus 10 is exemplified in the above explanation as a semiconductor manufacturing apparatus according to one embodiment, a plasma processing apparatus 10 may be, for example, a plasma CVD (Chemical Vapor Deposition) apparatus and, a sputtering apparatus, an ashing apparatus, and the like, which employs plasma.

Additionally, a support plate according to the embodiment may be applied to a single-wafer CVD apparatus, and an annealing apparatus, a thermal oxidization apparatus, rather than a plasma processing apparatus.

Additionally, although the spacer 21S having a shape of cylinder is described in the above embodiment, the spacer 21S may have a shape of, for example but not limiting to, polygonal column. However, the spacer 21S may have a shape of polygonal column having a flat side face of which area is relatively small, in order to avert the force applied to the spacer 21S from the adhesive AD. Moreover, in this case, a corner defined by two adjacent faces of the polygonal column may be directed toward the center of the top plate 21U.

Additionally, another spacer, which is similar to the spacer 21S, may be prepared, and a protrusive portion or a pointed portion may be provided on a back surface of the another spacer. Then, by providing the base plate 21B with a hole corresponding to the protrusive portion or the pointed portion, and inserting the protrusive portion or the pointed portion into the hole, such a spacer may be fixed therein so that relative movement of the spacer with respect to the base plate 21B is restrained.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate support plate comprising:
a base plate;
at least one spacer arranged on the base plate such that the at least one spacer is restrained from moving relative to the base plate without resort to an adhesive; and
a top plate having an upper surface capable of holding a substrate thereon, the top plate being fixed to the base plate with the at least one spacer therebetween.

2. The substrate support plate according to claim 1, wherein the base plate has a depressed portion receivable of a lower portion of the spacer.

3. The substrate support plate according to claim 1, wherein the top plate has a depressed portion receivable of an upper portion of the spacer.

4. The substrate support plate according to claim 1, wherein the spacer protrudes from the base plate as a single body with the base plate.

5. The substrate support plate according to claim 1, wherein an adhesive is filled between the base plate and the top plate.

6. The substrate support plate according to claim 1, wherein the at least one spacer comprises a plurality of spacers.

7. The substrate support plate according to claim 6, wherein the plurality of spacers are arranged radially on the base plate.

8. The substrate support plate according to claim 6, wherein the plurality of spacers are arranged along a plurality of straight lines that pass through a center of the base plate and are apart at equal angular intervals.

9. The substrate support plate according to claim 6, wherein the plurality of spacers are arranged along concentric circles.

10. The substrate support plate according to claim 6, wherein the plurality of spacers are arranged in matrix.

11. The substrate support plate according to claim 1, wherein the at least one spacer has a shape of column or polygonal column.

12. A semiconductor device manufacturing apparatus comprising:
a chamber; and
a substrate support plate provided inside the chamber, the substrate support plate including a base plate,
at least one spacer arranged on the base plate such that the at least one spacer is restrained from moving relative to the base plate without resort to an adhesive, and
a top plate having an upper surface capable of holding a substrate thereon, the top plate being fixed to the base plate with the at least one spacer therebetween.

13. The semiconductor device manufacturing apparatus according to claim 12, wherein the base plate has a depressed portion receivable of a lower portion of the spacer.

14. The semiconductor device manufacturing apparatus according to claim 12, wherein the top plate has a depressed portion receivable of an upper portion of the spacer.

15. The semiconductor device manufacturing apparatus according to claim 12, wherein the spacer protrudes from the base plate as a single body with the base plate.

16. The semiconductor device manufacturing apparatus according to claim 12, wherein an adhesive is filled between the base plate and the top plate.

17. The semiconductor device manufacturing apparatus according to claim 12, wherein the at least one spacer comprises a plurality of spacers.

18. The semiconductor device manufacturing apparatus according to claim 17, wherein the plurality of spacers are arranged radially on the base plate.

19. The semiconductor device manufacturing apparatus according to claim 17, wherein the plurality of spacers are arranged along concentric circles.

20. The semiconductor device manufacturing apparatus according to claim 17, wherein the plurality of spacers are arranged in matrix.
